(19) United States
(12) Patent Application Publication
(10) Pub. No.: US 2025/0239436 A1
(43) Pub. Date: Jul. 24, 2025

(54) SEMICONDUCTOR WAFER PROCESSING APPARATUS

(71) Applicant: SAMSUNG ELECTRONICS CO., LTD., Suwon-si (KR)

(72) Inventors: Seongha JEONG, Suwon-si (KR); Ungsu Park, Suwon-si (KR); Haeyoon Choi, Suwon-si (KR); Kyungsun Kim, Suwon-si (KR); Myeongsoo Shin, Suwon-si (KR); Donghyun Kim, Suwon-si (KR); Hoyoung Jang, Suwons-si (KR); Kangmin Jeon, Suwon-si (KR); Kyunghyun Han, Suwon-si (KR)

(73) Assignee: SAMSUNG ELECTRONICS CO., LTD., Suwon-si (KR)

(21) Appl. No.: 18/774,340

(22) Filed: Jul. 16, 2024

(30) Foreign Application Priority Data
Jan. 22, 2024 (KR) 10-2024-0009344

(51) Int. Cl. H01J 37/32

(52) U.S. Cl. CPC H01J 37/3244; H01J 37/32568; H01J 37/32642; H01J 37/32669; H01J 2237/3343

(57) ABSTRACT

A semiconductor wafer processing apparatus is provided. The apparatus includes: a processing chamber having an internal space formed therein; a lower electrode configured to support a semiconductor wafer within the processing chamber; and an upper electrode facing the lower electrode. The upper electrode includes a shower head configured to supply plasma gas. A lower surface of the shower head has circular symmetry and: extends horizontally from a diametric center portion of the semiconductor wafer to a first point P1 in a radially outward direction, extends obliquely from the first point P1 to a second point P2 away from the semiconductor wafer in the radially outward direction, and extends horizontally from the second point P2 to a third point P3 in the radially outward direction.

### CROSS-REFERENCE TO RELATED APPLICATION

This application claims priority to Korean Patent Application No. 10-2024-0009344, filed on Jan. 22, 2024, with the Korean Intellectual Property Office, the disclosure of which is incorporated herein by reference in its entirety.

### BACKGROUND

### 1. Field

The present disclosure relates to a semiconductor wafer processing apparatus.

### 2. Description of Related Art

Among semiconductor processes for manufacturing a semiconductor device, a semiconductor wafer processing apparatus, using plasma processing, performs etching, physical vapor deposition (PVD), chemical vapor deposition (CVD), and resist removal deposition processes.

Recently, a highly integrated high aspect ratio contact (HARCs) etching process of a semiconductor wafer has been performed. In the HARCs etching process, a small angle of tilting in the plasma gas distribution forming a plasma process region may cause defects.

When plasma is generated in a semiconductor process, a sheath is formed between the plasma and a surface of the semiconductor wafer. The sheath is a phenomenon which occurs due to a difference in mobility of electrons and ions at an interface between plasma and surrounding materials.

An incident angle at which plasma ions are applied to the semiconductor wafer is inclined from a region in which a sheath layer thickness is thin to a region in which the sheath layer thickness is thick. Since the sheath layer thickness in the HARCs etching process is inversely proportional to plasma density, tilting occurs from a region with high plasma density to a region with low plasma density.

Tilting in the plasma process induces defects such as chipping of the substrate wafer, so research into reducing tilting and chipping defects in the semiconductor wafer by uniformly distributing plasma density on the semiconductor wafer is required.

In particular, as high frequencies are used in the semiconductor etching process, plasma density increases significantly in a center portion of the semiconductor wafer, causing problems, so research into a semiconductor wafer processing apparatus that can improve plasma density distribution, even when using high frequencies is required.

### SUMMARY

One or more example embodiments provide a semiconductor wafer processing apparatus which adjusts a process gap with a semiconductor wafer by providing a shower head with a lower surface that varies, thereby improving plasma density distribution within the process gap.

According to an aspect of an example embodiment, a semiconductor wafer processing apparatus includes: a processing chamber having an internal space formed therein; a lower electrode configured to support a semiconductor wafer within the processing chamber; and an upper electrode facing the lower electrode. The upper electrode includes a shower head configured to supply plasma gas. A lower surface of the shower head has circular symmetry and: extends horizontally from a diametric center portion of the semiconductor wafer to a first point P1 in a radially outward direction, extends obliquely from the first point P1 to a second point P2 away from the semiconductor wafer in the radially outward direction, and extends horizontally from the second point P2 to a third point P3 in the radially outward direction.

According to another aspect of an example embodiment, a semiconductor wafer processing apparatus includes: a processing chamber having an internal space formed therein; a lower electrode configured to support a semiconductor wafer within the processing chamber; and an upper electrode facing the lower electrode. The upper electrode includes a shower head configured to supply plasma gas. A distance from the semiconductor wafer to an upper surface of the shower head is G. The shower head has, from a lower surface of the shower head to a horizontal upper surface of the shower head, respective heights h(r) at respective positions along a radially outward direction. A process gap between the shower head and the semiconductor wafer has respective heights g(r), at respective positions along the radially outward direction, and the process gap g(r) corresponds to g(r)=G−h(r). The lower surface of the shower head has circular symmetry and includes at least two portions extending horizontally in the radially outward direction. One of the horizontally extending portions vertically overlaps a diametric center portion of the semiconductor wafer. A height of the process gap at the diametric center portion of the semiconductor wafer is less than a height of the process gap at a radial center portion of the semiconductor wafer.

### BRIEF DESCRIPTION OF DRAWINGS

The above and other aspects, features, and advantages will be more apparent from the following description of example embodiments, taken in conjunction with the accompanying drawings, in which:

FIG. 1 is a schematic cross-sectional view of a semiconductor wafer processing apparatus according to an example embodiment;

FIG. 2 is an enlarged cross-sectional view illustrating shapes of an upper electrode and a lower electrode of a semiconductor wafer processing apparatus according to an example embodiment;

FIG. 3 is a cross-sectional view illustrating correction of plasma density in a process gap between an upper electrode and a lower electrode of a semiconductor wafer processing apparatus when there is no magnetic zone according to an example embodiment;

FIG. 4 is a cross-sectional view illustrating correction of plasma density in the process gap between an upper electrode and a lower electrode of a semiconductor wafer processing apparatus when there is a magnetic zone according to an example embodiment;

FIG. 5 is a schematic plan view of a magnetic zone viewed from above according to an example embodiment; and

FIG. 6 is a schematic diagram illustrating generation of B field flux through a magnet in a magnetic zone according to an example embodiment.

### DETAILED DESCRIPTION

Hereinafter, example embodiments will be described with reference to the accompanying drawings.

Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. Shapes and sizes of elements in the drawings may be exaggerated for clear description, and elements indicated by the same reference numeral are the same elements in the drawings.

It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

Expressions such as “first” and “second” are used to distinguish one component from another, and do not limit the order and/or importance of the components. For example, a first element may be referred to as a second element, and similarly, a second element may be referred to as a first element.

Terms used herein are used to describe examples. Singular expressions include plural expressions unless the context clearly indicates otherwise.

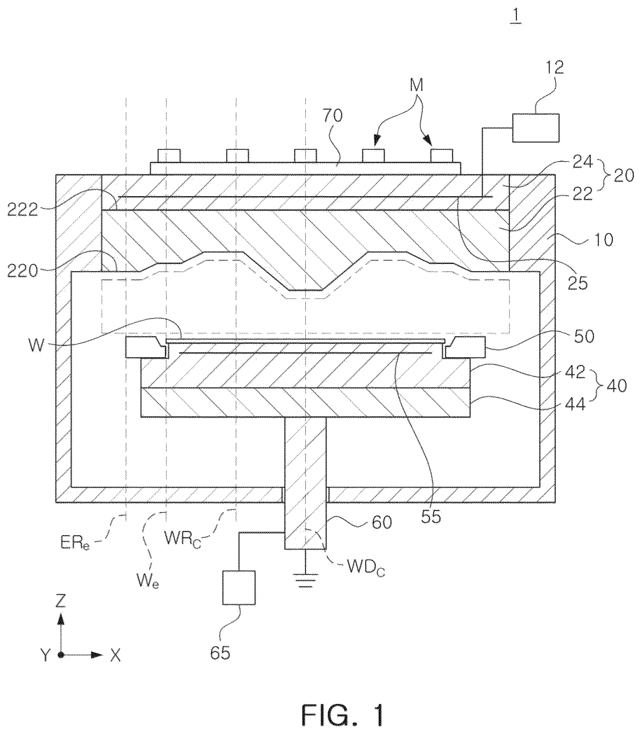

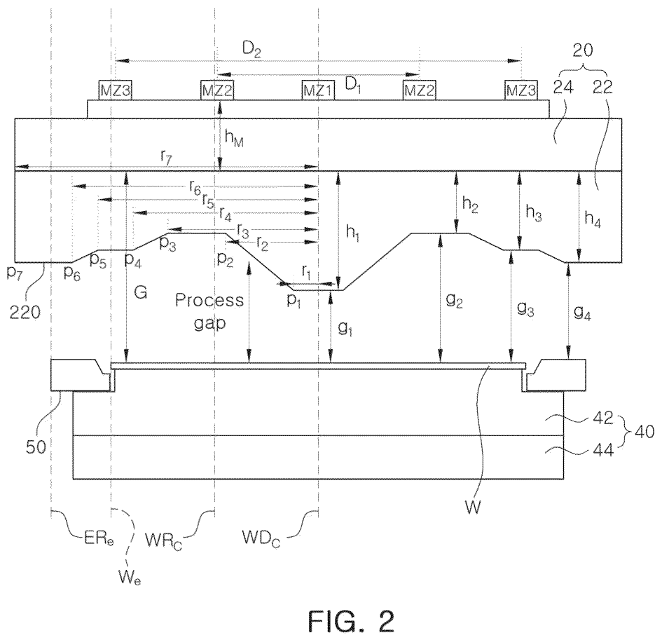

FIG. 1 is a schematic cross-sectional view of a semiconductor wafer processing apparatus according to an example embodiment, and FIG. 2 is an enlarged cross-sectional view illustrating shapes of an upper electrode and a lower electrode applied to the semiconductor wafer processing apparatus of FIG. 1.

A length direction and a width direction of the semiconductor wafer processing apparatus 1 may be referred to as an X-direction and a Y-direction, and a height direction may be referred to as a Z direction. When the semiconductor wafer processing apparatus 1 is cylindrical, the X-direction and the Y-direction may refer to radially outward directions of the semiconductor wafer W seated within the semiconductor wafer processing apparatus 1. For convenience of explanation, the X-direction is shown as a radial direction.

Referring to FIGS. 1 and 2, the semiconductor wafer processing apparatus 1 includes a processing chamber 10, an upper electrode 20, and a lower electrode 40.

The processing chamber 10 provides a space sealed from the outside for the semiconductor wafer W, and a process on the wafer W can be performed in the sealed space. The semiconductor process may include, for example, at least one of a deposition process, an etching process, or a cleaning process. Here, the etching process includes a high aspect ratio contact (HARC) etching process that may be performed to increase integration of semiconductor substrates.

The processing chamber 10 may be formed of a metal material such as aluminum (Al). In an example embodiment, the processing chamber 10 may include a substrate passage through which the semiconductor wafer W is loaded or unloaded.

The upper electrode 20 includes a shower head 22 and an upper plate 24. The shower head 22 introduces a process gas to the processing chamber 10 and discharges the process gas onto the semiconductor wafer W within the processing chamber 10.

A gas distribution structure configured to supply process gas to the shower head 22 or a cooler or heater configured to control a temperature of the shower head 22 may be embedded in the upper plate 24. In addition, an electrode 25 connected to a power supply device 12 outside the processing chamber 10 may be embedded in the upper plate 24, and the upper electrode 20 may interact with the lower electrode 40 supporting the semiconductor wafer W to form plasma P between the upper electrode 20 and the lower electrode 40.

The lower electrode 40 includes an electrostatic chuck 42 supporting the semiconductor wafer W within the processing chamber 10 and a lower plate 44 supporting the electrostatic chuck 42.

The electrostatic chuck 42 is an upper member supporting the semiconductor wafer W, and a distance from the shower head 22 may be adjusted by vertically moving (i.e., raising or lowering) a lift 60 by supplying power from a power supply device 65.

The electrostatic chuck 42 may be a susceptor including a heating pattern 55, and the heating pattern 55 may heat the susceptor using power supplied by the power supply device 65. For example, the susceptor may be formed of a ceramic material such as aluminum nitride (AlN), aluminum oxide (Al₂O₃), or the like.

When plasma gas is discharged from the shower head 22 and high frequency waves are applied to the upper electrode 20 and the lower electrode 40, plasma P is generated between the upper electrode 20 and the lower electrode 40. Plasma density is determined according to a processing gap between the upper electrode 20 and the lower electrode 40. When a shape of a lower surface 220 of the shower head 22 is constant and the processing gap is constant, plasma density becomes high at a diametric center of the semiconductor wafer W, and thus a thickness of a sheath layer is reduced, which may cause tilting of plasma ions outside of the diametric center of the semiconductor wafer W.

According to example embodiments, the shape of the lower surface 220 of the shower head 22 is changed (i.e., not planar) so that an upper portion of a region in which plasma P is generated has a shape corresponding to the lower surface 220 of the shower head 22. According to example embodiments, the lower surface 220 of the shower head 22 has circular symmetry around a center axis of the shower head 22. The center axis of the shower head 22 may correspond to a diametric center (WDc) region of the semiconductor wafer W. As a result, the processing gap in the diametric center (WDc) region of the semiconductor wafer W is reduced and plasma density is lowered, and relatively, the processing gap in a radial center (WRc) region of the semiconductor wafer W increases and plasma density increases. As described above, the sheath layer thickness on the semiconductor wafer is maintained to be constant, thereby improving tilting of plasma ions incident on the semiconductor wafer W by lowering plasma density in the diametric center (WDc) region of the semiconductor wafer W and increasing plasma density in the radial center (WRc) region of the semiconductor wafer W.

The shower head 22 according to an example embodiment has respective radial lengths r₁, r₂, r₃, r₄, r₅, r₆, and r₇ from the diametric center (WDc) region of the semiconductor wafer W to respective points P₁, P₂, P₃, P₄, P₅, P₆, and P₇ in the radially outward direction X.

The lower surface 220 of the shower head 22 includes a portion which extends horizontally from the diametric center (WDc) region of the semiconductor wafer W to a first point P₁ in the radially outward direction X, a portion which extends obliquely from the first point P₁ to a second point P₂ upwardly in a height direction Z in the radially outward direction X, away from the semiconductor wafer W, and a portion which extends further horizontally from the second point P₂ to a third point P₃ in the radially outward direction X.

Here, the radial center (WRc) region of the semiconductor wafer W is between the second point P₂ and the third point P₃.

In addition, the lower surface 220 of the shower head 22 includes a portion which extends further obliquely from the third point P₃ to a fourth point P₄ downwardly in a height direction Z in the radially outward direction X, to approach the semiconductor wafer W, a portion which extends further horizontally from the fourth point P₄ to a fifth point P₅ in the radially outward direction X, a portion which extends obliquely further from the fifth point P₅ to a sixth point P₆ downwardly in the height direction Z in the radially outward direction X, to approach the semiconductor wafer W, and a portion which extends further horizontally from the sixth point P₆ to a seventh point P₇ in the radially outward direction X.

A length from the diametric center (WDc) region of the semiconductor wafer W to the first point P₁ in the radially outward direction X may be defined as r₁, a length from the diametric center (WDc) region to the second point P₂ in the radial direction may be defined as r₂, a length from the diametric center (WDc) region to the third point P₃ in the radial direction may be defined as r₃, a length from the diametric center (WDc) region to the fourth point P₄ in the radial direction may be defined as r₄, a length from the diametric center (WDc) region to the fifth point P₅ in the radial direction may be defined as r₅, a length from the diametric center (WDc) region to the sixth point P₆ in the radial direction may be defined as r₆, and a length from the diametric center (WDc) region to the seventh point P₇ in the radial direction may be defined as r₇.

Here, the lower surface 220 of the shower head 22 has a horizontal surface between the first point P₁ and the diametric center (WDc) region, between the third point P₃ and the second point P₂, and between the sixth point P₆ and the seventh point P₇.

Here, the lower surface 220 of the shower head 22 satisfies a relationship (r₇−r₆)>(r₃−r₂)>r₁.

In addition, an end Wₑ of the semiconductor wafer W may be disposed between the fourth point P₄ and the fifth point P₅.

The semiconductor wafer processing apparatus 1 may further include an edge ring 50 provided on an outer circumference of the end Wₑ of the semiconductor wafer W.

An outer end ERₑ of the edge ring 50 is formed between the sixth point P₆ and the seventh point P₇ on the lower surface of the shower head 22. The lower surface of the shower head 22 corresponding to the outer end ERₑ of the edge ring 50 may be configured as a horizontal surface so that an interface of the plasma sheath may be horizontal with the surface of the semiconductor wafer W.

A height of the shower head 22 also affects a height of the processing gap at respective points (P₁, P₂, P₃, P₄, P₅, P₆, and P₇) between the upper electrode 20 and the lower electrode 40.

The height (h) of the shower head 22 from the lower surface 220 of the shower head 22 to the horizontal upper surface 222 of the shower head 22 has a respective height from the diametric center (WDc) region of the semiconductor wafer W to respective points in the radially outward direction.

Here, the height from the diametric center (WDc) region of the semiconductor wafer W to the first point P₁ may be defined as h₁, the height from the second point P₂ to the third point P₃ may be defined as h₂, the height from the fourth point P₄ to the fifth point P₅ may be defined as h₃, and the height from the sixth point P₆ to the seventh point P₇ may be defined as h₄.

Here, for flattening the plasma sheath, the heights may satisfy h₁>h₄>h₃>h₂.

In addition, a point on the lower surface 220 of the shower head 22 at which the height h of the shower head 22 is changed may be rounded. Here, the height h of the shower head 22 is a height to the horizontal upper surface 222 of the shower head 22, and is equal to the thickness of the shower head 22.

That is, if round processing is performed at a point at which the height (h) or thickness of the shower head 22 changes, a region in which plasma density changes will not be created.

Points along the radially outward direction from the diametric center (WDc) region of the semiconductor wafer W may be defined and designed as a process gap, that is gr.

The distance from the semiconductor wafer W to the upper surface 222 of the shower head 22 is defined as G, and the height of the shower head from the lower surface 220 of the shower head 22 to the horizontal upper surface 222 of the shower head 22 has a respective height, hᵣ, from the diametric center (WDc) region of the semiconductor wafer W to the respective points (P₁, P₂, P₃, P₄, P₅, P₆, and P₇) in the radially outward direction.

At the height from the upper surface of the semiconductor wafer (W) to the lower surface 220 of the shower head 22, each process gap, gᵣ, is formed from the diametric center (WDc) region of the semiconductor wafer to respective points P₁, P₂, P₃, P₄, P₅, P₆, and P₇ in the radially outward direction, and gᵣ is determined by gᵣ=G−hᵣ.

At least two portions extending horizontally may be provided in the radially outward direction from the diametric center (WDc) region of the semiconductor wafer W, and the horizontally extending portion may be formed in a portion in which the diametric center (WDc) region of the semiconductor wafer W corresponds to the radial center (WRc) region of the semiconductor wafer W.

As an example, when a semiconductor W with a wafer radius of 150 mm is etched, the semiconductor W has the following shape information.

TABLE 1

| Point | Section (r) | Radius (r, mm) | hᵣ | h(mm) | gᵣ |
|---|---|---|---|---|---|
| P₁ | 0~r₁ | 7 | h₁ | 19 | g₁ = G − h₁ |
| P₂ | r₁~r₂ | 60 | h₁ − (r − r₁)(h₂ − h₁)/(r₂ − r₁) | | G − h₁ + (r − r₁)(h₂ − h₁)/(r₂ − r₁) |
| P₃ | r₃~r₂ | 120 | h₂ | 9.5 | g₂ = G − h₂ |
| P₄ | r₄~r₃ | 149 | h₂ − (r − r₃)(h₃ − h₂)/(r₄ − r₃) | | G − h₂ + (r − r₃)(h₃ − h₂)/(r₄ − r₃) |
| P₅ | r₅~r₄ | 165 | h₃ | 11 | g₃ = G − h₃ |
| P₆ | r₆~r₅ | 176.4 | h₃ − (r − r₅)(h₄ − h₃)/(r₆ − r₅) | | G − h₃ + (r − r₅)(h₄ − h₃)/(r₆ − r₅) |
| P₇ | r₇~r₆ | 195 | h₄ | 17.5 | g₄ = G − h₄ |

Here, r is a radial length of the shower head 22 in a diametric center (WDc) region of the semiconductor wafer W.

The radial length r₄ is smaller than the radius (150 mm) of the semiconductor wafer W, so h₁, h₂, and h₃ may be thicknesses of the shower head 22 corresponding to the semiconductor wafer W. The process gaps at a point of the shower head 22 having the thicknesses h₁, h₂, and h₃ are g₁, g₂, and g₃, and a thickness of the shower head 22 in an outer region of the semiconductor wafer W corresponding to the shower head 22 having a thickness of h₄. The process gap g₄ is a distance between an edge ring 50 and the shower head 22.

Here, h₁>h₄>h₃>h₂ and g₂>g₃>g₄>g₁ can be satisfied.

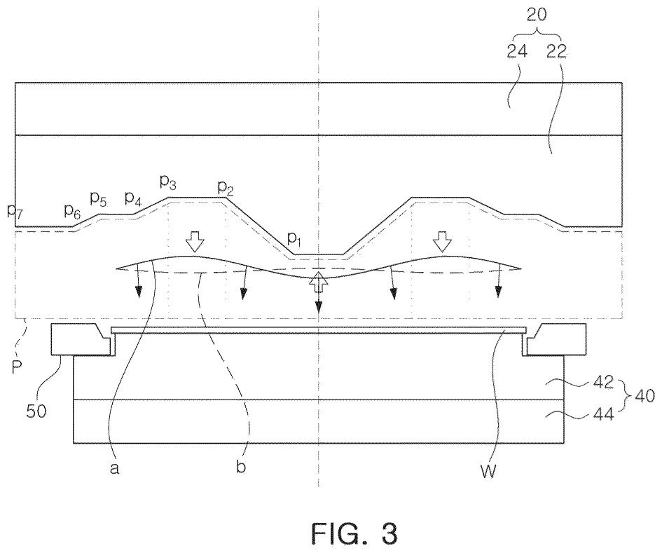

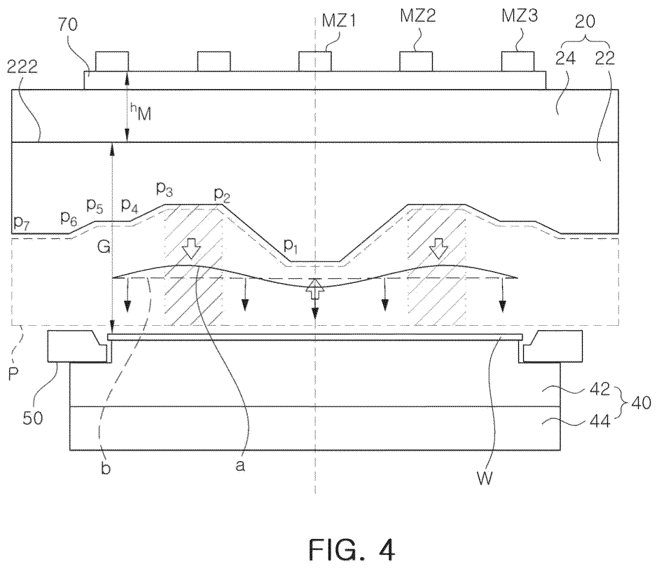

FIG. 3 is a cross-sectional view illustrating plasma density within a process gap between an upper electrode and a lower electrode when there is no magnetic zone, and FIG. 4 is a cross-sectional view illustrating plasma density within a process gap between an upper electrode and a lower electrode when there is a magnetic zone.

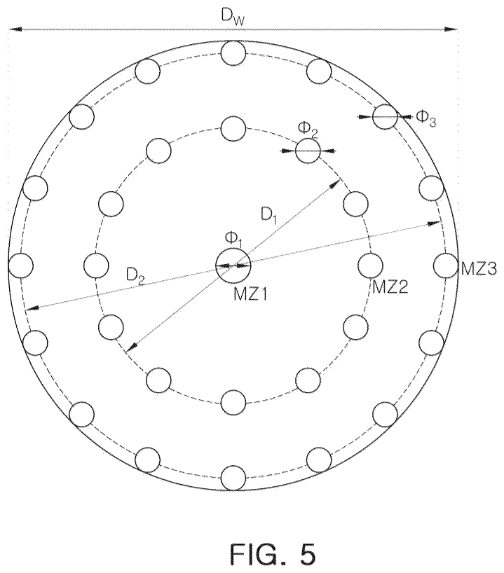

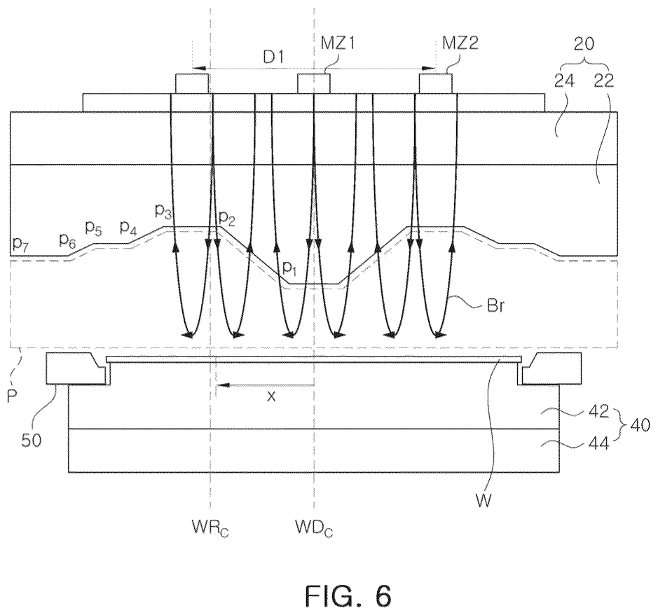

FIG. 5 is a schematic plan view of a magnetic zone viewed from above, and FIG. 6 is a schematic diagram illustrating generation of B field flux through a magnet in the magnetic zone.

FIG. 3 illustrates a case in which no magnets are disposed, and FIG. 4 illustrates a case in which a plurality of magnets M are disposed above an upper plate 24 of an upper electrode 20.

Referring to FIG. 3, plasma density distribution in a region in which plasma P is generated between the upper electrode 20 and the lower electrode 40 can be seen. A solid line a illustrates distribution of plasma density when a lower surface of the shower head 22 is flat, and a dotted line b illustrates a result of improving the distribution of plasma density by changing the shape of the lower surface 220 of the shower head 22 as discussed above with respect to FIGS. 1 and 2.

By changing the shape of the lower surface 220 of the shower head 22, plasma density in a center portion of the semiconductor wafer W may be lowered, and plasma density in a radial center portion of the semiconductor wafer W may be increased, so that plasma density distribution can be made uniform.

In order to achieve a more ideal uniform distribution of plasma density, a plurality of magnets M may be disposed above the upper plate 24 of the upper electrode 20, as shown in FIGS. 4 and 5.

Referring to FIGS. 4 and 5, the plurality of magnets M are provided within at least three magnetic zones MZ1, MZ2, and MZ3 on a concentric circle of the semiconductor wafer W.

In the first zone MZ1, one magnet is located at the exact center of the semiconductor wafer W.

The second zone MZ2 and the third zone MZ3 may have at least 12 magnets arranged at equal angles at positions along diameters D1 and D2. Here, D1 is a concentric circle diameter in the second zone MZ2, and D2 is a concentric circle diameter in the third zone MZ3.

To control plasma density, physical properties such as intensity or thickness of the magnets may be changed.

The diameters of the magnet in the first zone MZ1, the magnets in the second zone MZ2, and the magnets in the third zone MZ3 are Φ1, Φ2, and Φ3, respectively, and Φ1 may be larger than Φ2 or Φ3.

A height adjustment pad 70 may be provided between the upper plate 24 and the plurality of magnets M.

As shown in FIG. 4, a height from the semiconductor wafer W to an upper surface 222 of the shower head 22 may be defined as G, and a height from the upper surface 222 of the shower head 22 to bottom surfaces of the plurality of magnets M may be defined as h_{M}.

Here, radial B-field flux (Br) may be generated in the semiconductor wafer W by the magnet M, as shown in FIG. 6, and the radial B-field flux (Br) may be adjusted by physical properties and thickness of a magnet having a distance G+hₘ from an upper surface of the semiconductor wafer W.

The magnet disposed at a distance of G+hₘ from the upper surface of the semiconductor wafer W may be adjacent to the upper surface of the semiconductor wafer W so that electrons in the plasma collide to distribute plasma density more uniformly.

As shown in FIG. 6, when the magnet in the first zone MZ1 and the magnet in the second zone MZ2 are disposed in a position with a diameter of D1 of 180 nm and a distance of G+hₘ of 300 mm, plasma density in a region with a length of x (e.g., 80 mm) may increase, so that the thickness of the sheath layer may be further reduced.

When the magnet M is disposed above the upper electrode 20, more uniform plasma distribution can be obtained than by changing the shape of the shower head 22.

As set forth above, according to the semiconductor wafer processing apparatus, by adjusting a process gap with a semiconductor wafer by changing a shape of a lower surface of a shower head, and improving plasma density distribution within the process gap, etching defects of the wafer may be prevented.

In addition, by forming several magnetic zones above an upper electrode on a concentric circle of the semiconductor wafer, plasma density distribution may be further improved, so that a problem of etching defects of the semiconductor wafer may be improved and an efficient and stable process yield may be obtained.

While aspects of example embodiments have been shown and described, it will be apparent to those skilled in the art that modifications and variations could be made without departing from the scope of the present inventive concept as defined by the appended claims.

What is claimed is:

1. A semiconductor wafer processing apparatus comprising:
a processing chamber having an internal space formed therein;
a lower electrode configured to support a semiconductor wafer within the processing chamber; and
an upper electrode facing the lower electrode,
wherein the upper electrode comprises a shower head configured to supply plasma gas, and
wherein a lower surface of the shower head has circular symmetry and:
extends horizontally from a diametric center portion of the semiconductor wafer to a first point P1 in a radially outward direction,
extends obliquely from the first point P1 to a second point P2 away from the semiconductor wafer in the radially outward direction, and
extends horizontally from the second point P2 to a third point P3 in the radially outward direction.

2. The semiconductor wafer processing apparatus of claim 1, wherein the lower surface of the shower head:
extends obliquely from the third point P3 to a fourth point P4 to approach the semiconductor wafer in the radially outward direction,
extends horizontally from the fourth point P4 to a fifth point P5 in the radially outward direction,
extends obliquely from the fifth point P5 to a sixth point P6 to approach the semiconductor wafer in the radially outward direction, and
extends horizontally from the sixth point P6 to a seventh point P7 in the radially outward direction.

3. The semiconductor wafer processing apparatus of claim 2, when a length from the diametric center portion of the semiconductor wafer to the first point P1 in a radial direction is r1,
wherein a length from the diametric center portion of the semiconductor wafer to the second point P2 in the radial direction is r2,
wherein a length from the diametric center portion of the semiconductor wafer to the third point P3 in the radial direction is r3,
wherein a length from the diametric center portion of the semiconductor wafer to the fourth point P4 in the radial direction is r4,
wherein a length from the diametric center portion of the semiconductor wafer to the fifth point P5 in the radial direction is r5,
wherein a length from the diametric center portion of the semiconductor wafer to the sixth point P6 in the radial direction is r6,
wherein a length from the diametric center portion of the semiconductor wafer to the seventh point P7 in the radial direction is r7, and
wherein (r7−r6)>(r3−r2)>r1.

4. The semiconductor wafer processing apparatus of claim 3, wherein an end of the semiconductor wafer is between the fourth point P4 and the fifth point P5.

5. The semiconductor wafer processing apparatus of claim 3, further comprising an edge ring provided on an outer circumference of an end of the semiconductor wafer,
wherein an outer end of the edge ring is between the sixth point P6 and the seventh point P7.

6. The semiconductor wafer processing apparatus of claim 3, wherein the shower head has:
a height h1 between the diametric center portion of the semiconductor wafer and the first point P1,
a height h2 between the second point P2 and the third point P3,
a height h3 between the fourth point P4 and the fifth point P5,
a height h4 between the sixth point P6 and the seventh point P7, and wherein h1>h4>h3>h2.

7. The semiconductor wafer processing apparatus of claim 3, wherein the lower surface of the shower head is rounded at positions at which a height is changed.

8. The semiconductor wafer processing apparatus of claim 3, wherein the upper electrode further comprises an upper plate above the shower head, and
wherein the semiconductor wafer processing apparatus further comprises a plurality of magnets above the upper plate.

9. The semiconductor wafer processing apparatus of claim 8, wherein in a first magnetic zone, one magnet of the plurality of magnets vertically overlaps a center of the semiconductor wafer, and
wherein in each of a second magnetic zone and a third magnetic zone, at least 12 magnets of the plurality of magnets are provided at equal angles along each of diameters D1 and D2.

10. The semiconductor wafer processing apparatus of claim 9, wherein diameters of the one magnet in the first magnetic zone, the at least 12 magnets in the second magnetic zone, and the at least 12 magnets in the third magnetic zone are Φ1, Φ2, and Φ3, respectively, and
wherein Φ1>Φ2 or Φ3.

11. The semiconductor wafer processing apparatus of claim 8, further comprising a height adjustment pad between the upper plate and the plurality of magnets.

12. The semiconductor wafer processing apparatus of claim 8, wherein a distance from the semiconductor wafer to an upper surface of the shower head is G,
wherein a distance from the upper surface of the shower head to a bottom surface of the plurality of magnets is h_{M}, and
wherein radial B-field flux (Br) of the semiconductor wafer is based on physical properties and thickness of the plurality of magnets having a distance of G+h_{M} from the upper surface of the semiconductor wafer.

13. A semiconductor wafer processing apparatus, comprising:
a processing chamber having an internal space formed therein;
a lower electrode configured to support a semiconductor wafer within the processing chamber; and
an upper electrode facing the lower electrode,
wherein the upper electrode comprises a shower head configured to supply plasma gas,
wherein a distance from the semiconductor wafer to an upper surface of the shower head is G,
wherein the shower head has, from a lower surface of the shower head to a horizontal upper surface of the shower head, respective heights h(r) at respective positions along a radially outward direction,
wherein a process gap between the shower head and the semiconductor wafer has respective heights g(r), at respective positions along the radially outward direction, and the process gap g(r) corresponds to g(r)=G−h(r),
wherein the lower surface of the shower head has circular symmetry and comprises at least two portions extending horizontally in the radially outward direction, wherein one of the horizontally extending portions vertically overlaps a diametric center portion of the semiconductor wafer, and
wherein a height of the process gap at the diametric center portion of the semiconductor wafer is less than a height of the process gap at a radial center portion of the semiconductor wafer.

14. The semiconductor wafer processing apparatus of claim 13, wherein the lower surface:
extends horizontally from the diametric center portion of the semiconductor wafer to a first point P1 in the radially outward direction,
extends obliquely from the first point P1 to a second point P2 away from the semiconductor wafer in the radially outward direction,
extends horizontally from the second point P2 to a third point P3 in the radially outward direction,
extends obliquely from the third point P3 to a fourth point P4 to approach the semiconductor wafer in the radially outward direction,
extends horizontally from the fourth point P4 to a fifth point P5 in the radially outward direction,
extends obliquely from the fifth point P5 to a sixth point P6 to approach the semiconductor wafer in the radially outward direction, and
extends horizontally from the sixth point P6 to a seventh point P7 in the radially outward direction.

15. The semiconductor wafer processing apparatus of claim 14, when a length from the diametric center portion of the semiconductor wafer to the first point P1 in a radial direction is r1,
wherein a length from the diametric center portion of the semiconductor wafer to the second point P2 in the radial direction is r2,
wherein a length from the diametric center portion of the semiconductor wafer to the third point P3 in the radial direction is r3,
wherein a length from the diametric center portion of the semiconductor wafer to the fourth point P4 in the radial direction is r4,
wherein a length from the diametric center portion of the semiconductor wafer to the fifth point P5 in the radial direction is r5,
wherein a length from the diametric center portion of the semiconductor wafer to the sixth point P6 in the radial direction is r6,
wherein a length from the diametric center portion of the semiconductor wafer to the seventh point P7 in the radial direction is r7, and
wherein (r7−r6)>(r3−r2)>r1.

16. The semiconductor wafer processing apparatus of claim 15, wherein an end of the semiconductor wafer is between the fourth point P4 and the fifth point P5.

17. The semiconductor wafer processing apparatus of claim 15, further comprising an edge ring provided on an outer circumference of an end of the semiconductor wafer,
wherein an outer end of the edge ring is between the sixth point P6 and the seventh point P7.

18. The semiconductor wafer processing apparatus of claim 15, wherein the shower head has:
a height h1 between the diametric center portion of the semiconductor wafer and the first point P1,
a height h2 between the second point P2 and the third point P3,
a height h3 the fourth point P4 and the fifth point P5,
a height h4 between the sixth point P6 and the seventh point P7, and wherein h1>h4>h3>h2 and g2>g3>g4>g1.

19. The semiconductor wafer processing apparatus of claim 15, wherein the upper electrode further comprises an upper plate above the shower head,
wherein the semiconductor wafer processing apparatus further comprises a plurality of magnets are above the upper plate,
wherein in a first magnetic zone, one magnet of the plurality of magnets vertically overlaps a center of the semiconductor wafer, and
wherein in each of a second magnetic zone and a third magnetic zone, at least 12 magnets of the plurality of magnets are provided at equal angles along each of diameters of D1 and D2.

20. The semiconductor wafer processing apparatus of claim 19, wherein diameters of the one magnet in the first magnetic zone, the at least 12 magnets in the second magnetic zone, and the at least 12 magnets in the third magnetic zone are Φ1, Φ2, and Φ3, respectively, and
wherein Φ1>Φ2 or Φ3.
